(19) United States
(12) Patent Application Publication
(10) Pub. No.: US 2023/0134061 A1
(43) Pub. Date: May 4, 2023

(54) SHOWERHEAD PURGE COLLAR

(71) Applicant: Lam Research Corporation, Fremont, CA (US)

(72) Inventors: Bradley Taylor Streng, Tigard, OR (US); Sumit Subhash Singh, Pune (IN)

(21) Appl. No.: 17/911,992

(22) PCT Filed: Mar. 16, 2021
(86) PCT No.: PCT/US2021/022637

§ 371 Date: Sep. 15, 2022

(30) Foreign Application Priority Data
Mar. 19, 2020 (IN) 202031011832

(51) Int. Cl. C23C 16/455; C23C 16/44; C23C 16/505; H01J 37/32

(52) U.S. Cl. CPC C23C 16/45565; C23C 16/505; C23C 16/4408; H01J 37/3244; H01J 2237/332

(57) ABSTRACT

Methods, systems, and computer programs are directed to the design of a new showerhead purge collar for a semiconductor manufacturing apparatus. The showerhead purge collar includes a top section and a bottom section coupled to the top section and concentric with the top section. The top section has a hollow center to conduct process gas and an inlet for a purge gas on a side of the top section. The bottom section has a hollow center to conduct the process gas towards a showerhead. A plenum to conduct the purge gas is defined within the showerhead purge collar, and the bottom section includes holes to exhaust the purge gas above the showerhead.

### CLAIM OF PRIORITY

This application claims the benefit of priority under to Indian Patent Application No. 202031011832, filed on Mar. 19, 2020, which is incorporated by reference herein in its entirety.

### TECHNICAL FIELD

The subject matter disclosed herein generally relates to a showerhead purge collar in a semiconductor manufacturing apparatus.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In some semiconductor apparatus, e.g., Atomic Layer Deposition (ALD) apparatus, problems may arise relating to material buildup on the back of the showerhead . Undesired particles formed on the showerhead can fall on the substrate, resulting in damage to the substrate.

In some operations, a purge-gas plenum exists between the showerhead stem and the inner diameter of the purge collar . This design causes the purge gas to be pinched off when the showerhead stem is tilted or not centered perfectly. This tilting and off-centering causes purge gas non-uniformity, which leads to showerhead backside deposition and flaking particles.

What is needed is a showerhead purge collar that provides better purge-gas flow, which is not affected by showerhead tilting or centering, to avoid the backside deposition on the showerhead.

### SUMMARY

In one aspect, a showerhead purge collar includes an internal plenum for the purge gas so the showerhead purge collar is not affected by showerhead stem tilting and non-centering. The purge gas outlet holes are sized, located, and oriented to provide optimal showerhead backside purging uniformity.

In one aspect, the showerhead purge collar is formed with a multi-piece laminated ceramic structure. The ceramic structure could also be 3D printed to create the internal purge cavity without requiring multiple ceramic pieces to be laminated together. The new showerhead purge collar decouples the showerhead purge uniformity from the stem concentricity and angle. The size, location, and orientation of the purge holes in the design are selected based on in-depth flow modeling to produce optimum purge uniformity . The design moves the purge plenum into the purge collar so it is unaffected by showerhead stem tilting and concentricity.

Some benefits of the showerhead purge collar include:
the showerhead backside purge gas uniformity is not affected by showerhead tilting or centering,
the design is a single piece construction, resulting in little or no change in the way the showerhead purge collar is assembled or installed on the tool in manufacturing,
the design reduces or eliminates showerhead backside deposition and resulting particles, and
the impact for upgrading current customers is very low.

One general aspect includes a showerhead purge collar comprising a top section and a bottom section coupled to the top section and concentric with the top section. The top section has a hollow center to conduct process gas and an inlet for a purge gas on a side of the top section. The bottom section has a hollow center to conduct the process gas towards a showerhead. A plenum to conduct the purge gas is defined within the showerhead purge collar, and the bottom section includes holes to exhaust the purge gas above the showerhead

Another general aspect is for a method for manufacturing a showerhead purge collar. The method includes an operation for making a top section of ceramic material. The top section has a hollow center for conducting process gas and an inlet for a purge gas on a side of the top section. Further, the method includes an operation for making a bottom section of the ceramic material, where the bottom section has a hollow center for conducting the process gas towards a showerhead. The method further includes operations for drilling holes in the bottom section for exhausting the purge gas above the showerhead, and for bonding together the top section and the bottom section. The bottom section is concentric with the top section, and a plenum for conducting the purge gas is defined within the showerhead purge collar.

### BRIEF DESCRIPTION OF THE DRAWINGS

Various of the appended drawings merely illustrate example embodiments of the present disclosure and cannot be considered as limiting its scope.

FIG. 1 illustrates an in-situ deposition system in accordance with one example embodiment.

FIG. 2 shows the location of the showerhead purge collar, according to some example embodiments.

FIG. 3 is a representation of the flow volume around the showerhead and pedestal assemblies, according to some example embodiments.

FIG. 4 is a first design for the showerhead purge collar, according to some example embodiments.

FIG. 5 illustrates the formation of deposits on the showerhead, according to some example embodiments.

FIG. 6 is an improved showerhead purge collar, according to some example embodiments.

FIG. 7 is a detail of the bottom portion of the showerhead purge collar, according to some example embodiments.

FIG. 8 is a bottom view of the showerhead purge collar, according to some example embodiments.

FIG. 9 is a perspective view of the top portion of the showerhead purge collar, according to some example embodiments.

FIG. 10 is wireline representation of the showerhead purge collar, according to some example embodiments.

FIG. 11 shows a cross section of the showerhead purge collar with some details of the internal geometry, according to some example embodiments.

FIGS. 12A-12D show experiment results for the showerhead purge collar designs, according to some example embodiments.

FIG. 13 is a flowchart of a method for manufacturing the showerhead purge collar, according to some example embodiments.

### DETAILED DESCRIPTION

Example methods, systems, and computer programs are directed to the design of a new showerhead purge collar. Examples merely typify possible variations.

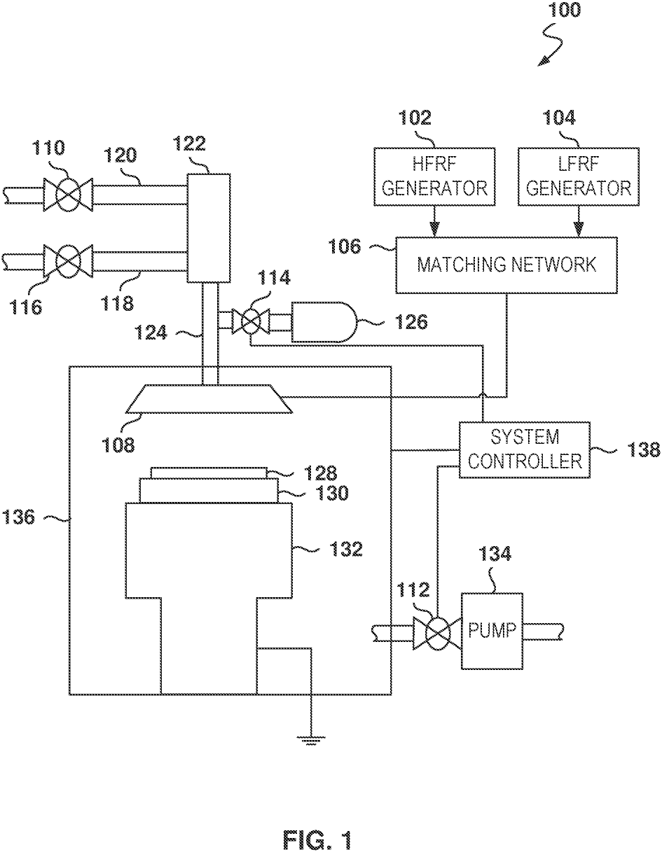

FIG. 1 illustrates an in-situ deposition system in accordance with one example embodiment. As an example, deposition techniques provided herein may be implemented in a plasma-enhanced chemical vapor deposition (PECVD) reactor or a conformal film deposition (CFD) reactor. Such a reactor may take many forms and may be part of an apparatus that includes one or more chambers or reactors-sometimes including multiple stations-that may each house one or more wafers and may be configured to perform various wafer operations. The one or more chambers may maintain the wafer in a defined position or positions (with or without motion within that position, e.g., rotation, vibration, or other agitation). In one implementation, prior to operations performed in disclosed embodiments, a wafer undergoing film deposition may be transferred from one station to another within a reactor or chamber during the process. In other implementations, the wafer may be transferred from chamber to chamber within the apparatus to perform different operations. Full deposition or any fraction of the total film thickness for any deposition step may occur entirely at a single station. While in process, each wafer may be held in place by a pedestal, wafer chuck, and/or other wafer-holding apparatus. For certain operations in which the wafer is to be heated, the apparatus may include a heater, such as a heating plate. A Vector™ (e.g.. C3 Vector) or Sequel™ (e.g., C2 Sequel) reactor, produced by Lam Research Corp. of Fremont, Calif., are both examples of suitable reactors that may be used to implement the techniques described herein.

FIG. 1 provides a block diagram depicting various reactor components arranged for implementing methods described herein. As shown, a reactor system 100 includes a process chamber 136 that encloses other components of the reactor system 100 and serves to contain plasma generated by a capacitive-discharge type system including a showerhead 108 working in conjunction with a grounded heater block 132. A high frequency (HF) radio frequency (RF) HFRF generator 102 and a low frequency (LF) radio frequency (RF) LFRF generator 104 is connected to a matching network 106 and to the showerhead 108. The power and frequency supplied by the matching network 106 may be sufficient to generate a plasma from process gases supplied to the process chamber 136. In a typical process, the HFRF component may generally be between 5 MHz to 60 MHz, e.g., 13.56 MHz. In operations where there is an LF component, the LF component may be from about 100 kHz to 2 MHz, e.g., 430 kHz.

Within the process chamber 136, a pedestal 130 supports a substrate (e.g., wafer 128). The pedestal 130 includes a chuck, a fork (not shown), or lift pins (not shown) to hold and transfer the wafer 128 into and out of the process chamber 136 between operations. The chuck may be an electrostatic chuck, a mechanical chuck, or various other types of chuck as are available for use in the industry and/or for research.

Various process gases may be introduced via inlet 124. Multiple source gas lines (e.g., gas line 118, gas line 120) are connected to a manifold 122. The gases may or may not be premixed. Corresponding valving and mass flow control mechanisms (e.g.. valve 110, valve 116) may be employed to ensure that the correct process gases are delivered during the deposition and plasma treatment phases of each operation in the process. In the case where a chemical precursor(s) is delivered in liquid form, liquid flow control mechanisms may be employed. Such liquids may then be vaporized and mixed with process gases during transportation in a manifold heated above the vaporization point of the chemical precursor supplied in liquid form before reaching the process chamber 136.

A dispenser 114 connects to the inlet 124. The dispenser 114 dispenses chemicals such as TMA, zinc, magnesium, or fluorine contained in a vial 126 that is coupled to the dispenser 114. In one example embodiment, the precursor in the vial 126 includes chemicals (e.g., TMA) that coat an interior wall of the process chamber 136. These coatings prevent diffusion and/or release of substrate materials (e.g., aluminum), prevent chemical attack (e.g.. fluorine), provide desired electrical properties, or repair damage to the surface (e.g., from in situ cleans.

Process gases may exit process chamber 136 via an outlet 112. A vacuum pump 134 (e.g., a one or two stage mechanical dry pump and/or turbomolecular pump), may be used to draw process gases out of the process chamber 136 and to maintain a suitably low pressure within the process chamber 136 by using a closed-loop-controlled flow restriction device (not shown), such as a throttle valve or a pendulum valve.

As discussed above, the techniques for deposition discussed herein may be implemented on a multi-station or single station tool. In some implementations, tools for processing 450 mm wafers may be used. In various implementations, the wafers may be indexed after every deposition process, or may be indexed after etching steps if the etching chambers or stations are also part of the same tool, or multiple depositions and treatments may be conducted at a single station before indexing the wafer. In some implementations, the wafers may be indexed after each layer is deposited, such as after an underlayer is deposited, or after an atomically smooth layer is deposited.

In some embodiments, an apparatus may be provided that is configured to perform the techniques described herein. A suitable apparatus may include hardware for performing various process operations as well as a system controller 138 having instructions for controlling process operations in accordance with the disclosed embodiments. The system controller 138 includes one or more memory devices and one or more processors communicatively connected with various process control equipment, e.g., valves, RF generators, wafer handling systems, etc., and configured to execute the instructions so that the apparatus will perform a technique in accordance with the disclosed embodiments. Machine-readable media containing instructions for controlling process operations in accordance with the present disclosure may be coupled to the system controller 138. The system controller 138 may be communicatively connected with various hardware devices, e.g., dispenser 114, mass flow controllers, valves, RF generators, vacuum pumps, etc. to facilitate control of the various process parameters that are associated with the deposition operations as described herein.

In some embodiments, the system controller 138 controls all of the activities of the reactor system 100. The system controller 138 may execute system control software stored in a mass storage device, loaded into a memory device, and executed on a processor. Alternatively, the control logic may be hard coded in the system controller 138. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. The system control software may include instructions for controlling the timing of dispensing chemicals from the vial 126, the timing of gas flows, wafer movement. RF generator activation, etc., as well as instructions for controlling the mixture of gases, the chamber and/or station pressure, the chamber and/or station temperature, the wafer temperature, the target power levels, the RF power levels, the substrate pedestal, chuck, and/or susceptor position, and other parameters of a particular process performed by the reactor system 100. The system control software may be configured in any suitable way. For example, various process tool component subroutines or control objects may be written to control operation of the process tool components necessary to carry out various process tool processes. The system control software may be coded in any suitable computer readable programming language.

The system controller 138 may typically include one or more memory devices and one or more processors configured to execute the instructions so that the apparatus will perform a technique in accordance with the present disclosure. Machine-readable media containing instructions for controlling process operations in accordance with disclosed embodiments may be coupled to the system controller 138.

The method and apparatus described herein may be used in conjunction with lithographic patterning tools or processes such as those described below for fabrication or manufacture of semiconductor devices, displays, LEDs, photovoltaic panels, and the like Typically, though not necessarily, such tools/processes will be used or conducted together in a common fabrication facility. Lithographic patterning of a film typically includes some or all of the following steps, each step performed with a number of possible tools: (1) application of photoresist on a workpiece, (e.g., substrate or multi-layer stack as provided in disclosed embodiments), using a spin-on or spray-on tool; (2) curing a photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferred the resist pattern into an underlying film or workpiece, such as an amorphous carbon underlayer, by using a dry or plasma-assisted etching tool; and (6) removing the resist using a tool such as an RF or microwave plasma resist stripper.

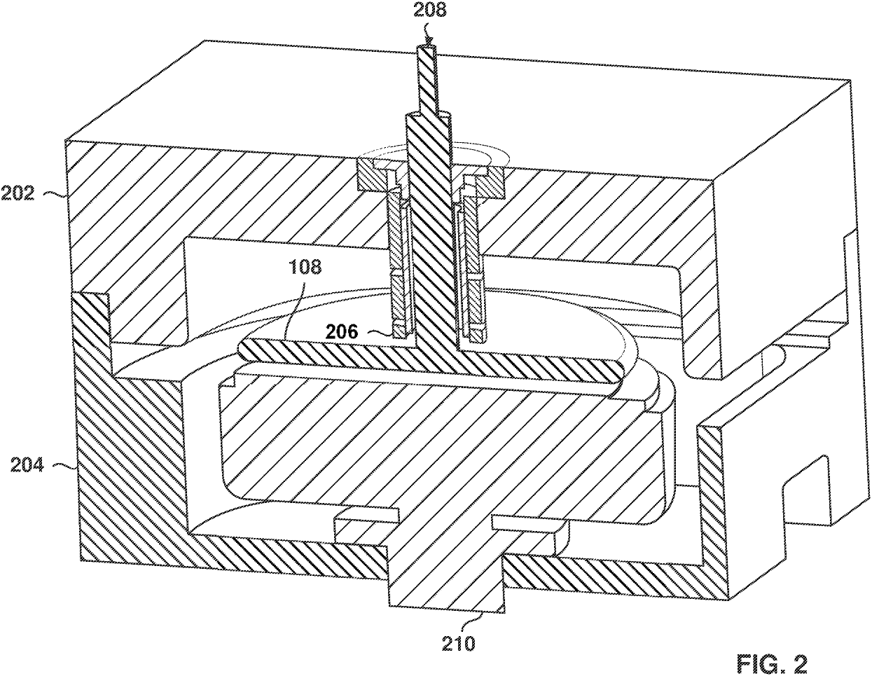

FIG. 2 shows the location of the showerhead purge collar 206, according to some example embodiments. The gases flow through the center opening 208 of the showerhead purge collar 206 into the chamber. In some example embodiments, the showerhead 108, situated on the chamber top wall 202, lines the top part of the chamber and the gases enter the chamber through the showerhead 108. The chamber bottom wall 204 holds the pedestal 210 that supports the substrate during operation of the semiconductor manufacturing apparatus.

The showerhead purge collar 206 surrounds the center opening 208 and an inert gas (e.g., Nitrogen) flows through the showerhead purge collar 206 towards the bottom, above the showerhead 108, and is dispersed annularly around the top of the showerhead to exit towards the bottom of the chamber. There are slots on the showerhead purge collar 206 that allow the inert gas to flow inside the chamber top wall 202.

The purpose of having the purge gas is to prevent the gases that come out of the showerhead (e.g., deposition-type gases) to build up on the showerhead or above the showerhead. If there is not a good purge, the gases may recirculate above the showerhead and create the undesired accumulation of particles on the showerhead.

During operation of the semiconductor manufacturing apparatus, the showerhead 108 may not perfectly parallel to the pedestal 210, which means that the face of the showerhead is not perfectly parallel to the substrate. There is a mechanism to adjust the plane of the face of the showerhead 108 to make it parallel to the pedestal 210, e.g., adjusting the showerhead by 1°. Additionally, the showerhead 108 may not be perfectly centered about the pedestal 210.

However, these adjustments will often cause the purge gas to flow non-uniformly over the whole area of the substrate. The purge gas may be pinched in one side and have different flow rates on the circumference of the showerhead purge collar 206. These small adjustments can cause big changes in the purge-gas flow and create areas of small flow that are susceptible to depositions on the back of the showerhead 108.

Experiments showed that a 1° tilt of the showerhead 108 may cause flow rates to be twice as much, or more, in some parts of the chamber top wall 202 than in others, which creates undesired non-uniformity. Sometimes, portions of the showerhead may receive very small amounts of purge gas.

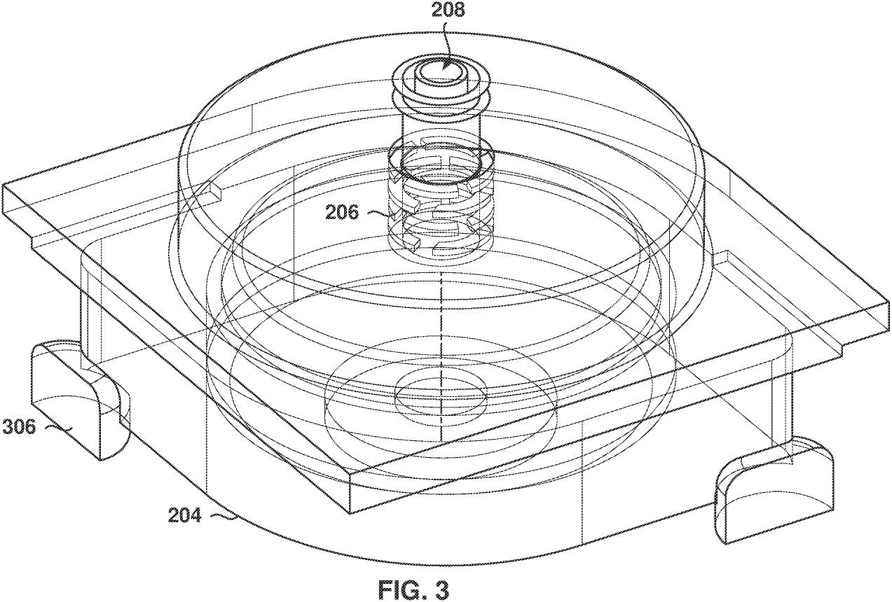

FIG. 3 is a representation of the flow volume around the showerhead and pedestal assemblies, according to some example embodiments. A purge inlet 302 is the entry point for the purge gas into the showerhead purge collar 206. The purge gas exits the showerhead purge collar 206 through the slots on the side and the purge gas circulates around the showerhead and towards the gas outlets 306, which are connected to the gas vacuum exhaust pump to exhaust the purge gas and the process gasses.

In some example embodiments, there are two gas outlets 306 on opposite corners at the bottom of the chamber 204 by the pedestal. The gas that flows out of the showerhead purge collar 206 near one of the outlets 306 has a direct path and flows easily: however, gas that comes out in one of the other corners has to flow around the bottom, near the showerhead, and towards one of the outlets 306. This longer flow path can create problem areas where the gas flow can recirculate and entrain deposition materials above the showerhead.

In some example embodiments, a baffle plate (not shown) is used at the chamber bottom to improve the flow in all directions and make the flow uniform. The baffle plate is placed under the pedestal.

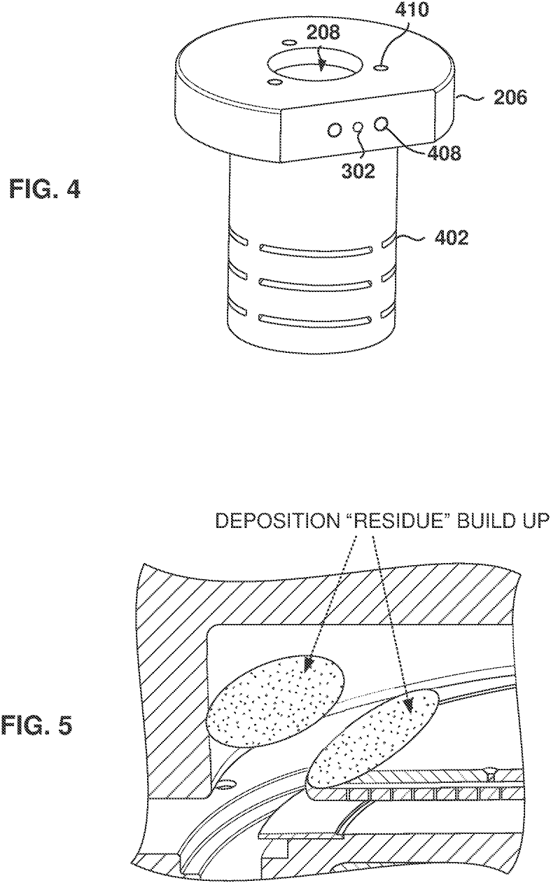

FIG. 4 is a first design for the showerhead purge collar 206, according to some example embodiments. The showerhead purge collar 206 is the one illustrated in FIGS. 2-3. The purge gas enters the showerhead purge collar 206 through inlet 302 and flows down the showerhead purge collar 206 to exit through slots 402. In some example embodiments, three rows of slots 402 are provided and each row includes four slots 402. but other embodiments may use a different number of rows and a different number of slots per row.

The process gas enters through the center opening 208 and flows down to exit at the bottom of the showerhead purge collar 206. Mounting holes 408 are used to mount the purge gas line. Three holes 410 in the top of the showerhead purge collar 206 are used to mount the showerhead purge collar 206 to the adjustment mechanism and the top plate.

FIG. 5 illustrates the formation of deposits on the showerhead, according to some example embodiments. FIG. 5 shows the area around the left side of the showerhead 108. After operating the chamber, deposition residues build up were found above the showerhead 108 and on the walls of the chamber top wall 202. This is an indication that the chamber top wall 202 is getting precursor that recirculates, builds up, and then flakes off to migrates to the surface of the substrate.

The process gases, in some examples, include one or more of Argon, Oxygen, N₂O, and N₂, at flow rates between 4000 and 25000 standard cubic centimeters per minute (SCCM). In some example embodiments, the purge gas is N₂ at 25000 SCCM, but other purge gases and flow rates may be used.

One of the challenges of changing the design of the showerhead purge collar 206 is that users have already well-established deposition processes, and the users do not want to have to redesign all their processes. Also, users want a replacement part that fits within the existing configuration, without expensive replacement operations of the structure of the chamber. The goal is to change the showerhead purge collar 206 so that it can be replaced without redesigning the chamber and improve the purge-gas flow.

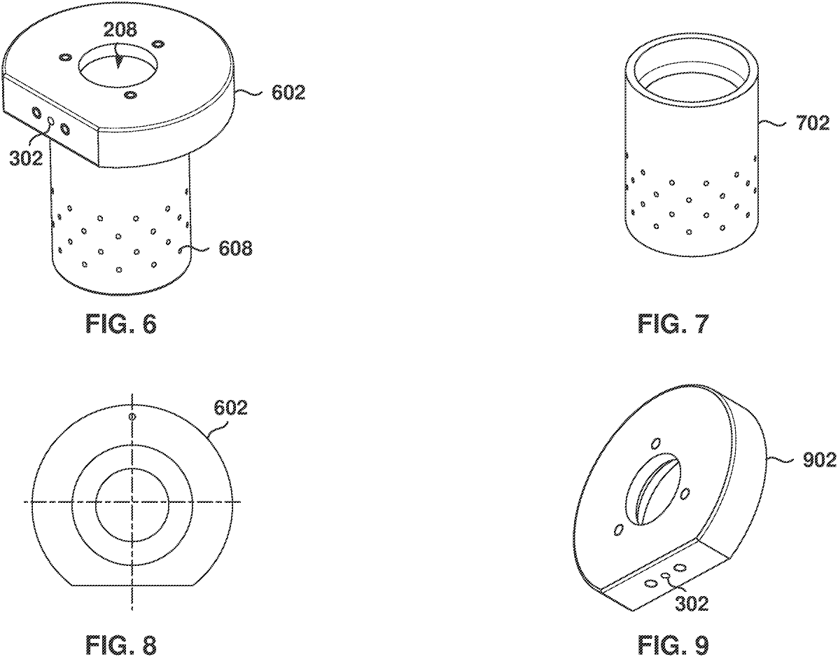

FIG. 6 is an improved showerhead purge collar 602, according to some example embodiments. The showerhead purge collar 602 replaces the venting slots around the bottom section with holes 608 distributed throughout the side.

In some example embodiments, there are four rows of holes 608 and each row has 12 holes evenly distributed around the circumference of the showerhead purge collar 602; that is, each hole is separated 30° from neighbor holes in the same row, the 30° being measured from the center of the showerhead purge collar 602 as viewed from the top. The holes on one row are spaced vertically between the holes in the row above or below; that is, as viewed from the top, the holes would be separated 15°.

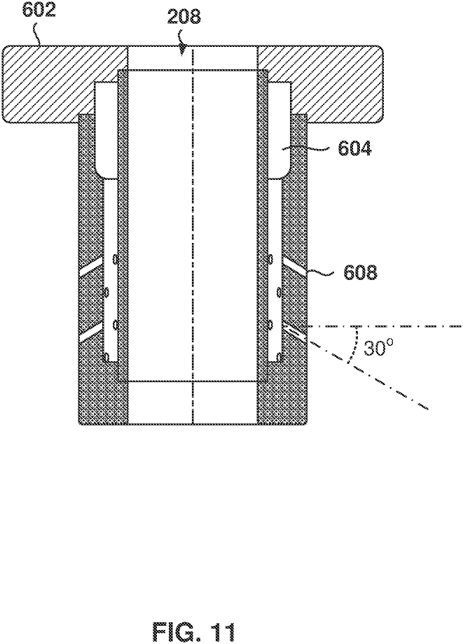

Further, each hole 608 is a cylindrical hole going from the inside of the showerhead purge collar 602 to the outside. However, the cylinders are angled downwards, such as at -30° angle as measured from a horizontal plane. More details are provided below with reference to FIG. 11 regarding the structure of the holes 608.

In some example embodiments, the holes 608 are 0.1 inches (2.54 mm) in diameter, but other embodiments may use other hole sizes. Further, the holes sizes may vary by row to control the flow of purge gas at different heights.

In other example embodiments, each row has 18 holes, which showed proper purge-gas flow performance during experiments. However, the increase in the number of holes increased the cost of manufacturing without a big improvement in purge performance.

It is noted that the embodiments illustrated in FIG. 6 are examples and do not describe every possible embodiment. Other embodiments may utilize a different number of rows (e.g., in the range from 2 to 6, or in the range from 1 to 10), a different number of holes per row (e.g., in the range from 4 to 50, or in the range from 6 to 24), different hole sizes (e.g.. in the range from 2 mm to 3 mm, or in the range from 1 mm to 5 mm, or in the range from 0.1 mm to 6 mm), and different angles for the holes (e.g., in the range from 0° to -70° from the horizontal plane). The embodiments illustrated in FIG. 6 should therefore not be interpreted to be exclusive or limiting, but rather illustrative.

The selection of the illustrated configuration in FIG. 6 was the result of testing and optimization performed over several months in order to produce the adequate purge-gas flow. For example, experiments showed that having the holes of the different rows aligned vertically produced worse purge-gas flow.

In some example embodiments, the showerhead purge collar 602 includes two parts: a bottom section 702 and a top section 902. FIG. 7 is a detail of the bottom section 702 of the showerhead purge collar 602, according to some example embodiments. FIG. 8 is a bottom view of the showerhead purge collar 602, according to some example embodiments, which shows a dowel pin hole on the bottom side of the top portion of the collar. FIG. 9 is a perspective view of the top section 902 of the showerhead purge collar 602, according to some example embodiments.

The top section 902 has the shape of a short, hollow cylinder where a section has been taken out by a straight downward cut. The resulting flat surface includes the purge inlet 302 and the purge gas line mounting holes. The bottom section 702 is also a hollow cylinder and includes the holes 608.

In some example embodiments, the top section 902 and the bottom section 702 are ceramic parts that are bonded together to form the showerhead purge collar 602. The two parts are diffusion bonded together to form a plenum for the purge gas, as illustrated in FIG. 11. Because the parts are ceramic, adding more holes increases the cost of the manufacturing process.

In another example embodiments, the showerhead purge collar 602 is created with 3D printing: therefore, no bonding of ceramic parts is required.

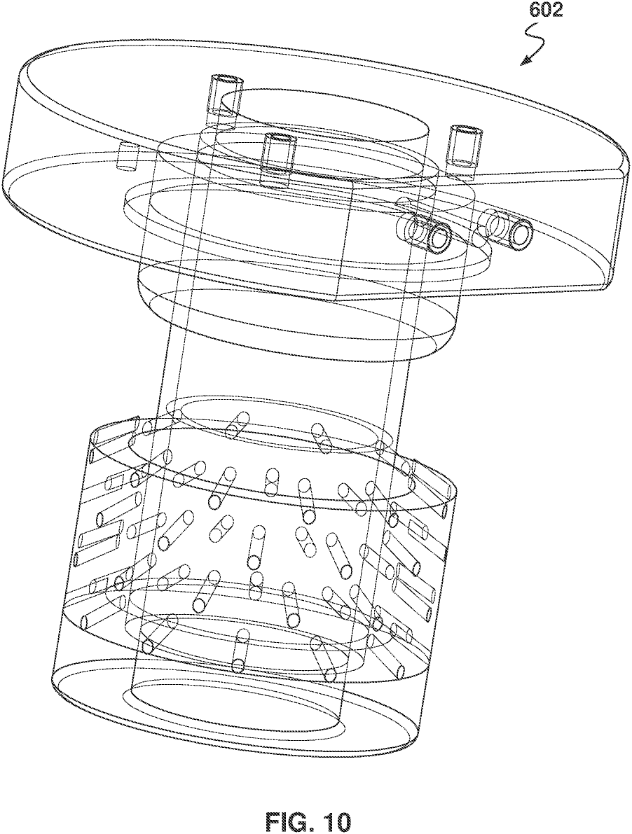

FIG. 10 is wireline representation of the showerhead purge collar 602, according to some example embodiments. FIG. 10 shows how the holes are angled downwards and are disposed between the inner surface of the center hole and the outside of the showerhead purge collar 602.

FIG. 11 shows a cross section of the showerhead purge collar 602 with some details of the internal geometry, according to some example embodiments. A plenum 604 is formed inside the showerhead purge collar 602. next to the center opening 208 where the process gasses flow. FIG. 11 also illustrates how the holes 608 are angled downwards (only a few holes are illustrated for simplicity).

Since the plenum 604 is inside the showerhead purge collar 602, tilting or centering of the showerhead does not affect the flow of the purge gas. That is, the showerhead movement does not pinch the flow of the purge gas.

By angling the holes downwards, experiments demonstrated that the purge gas flows at a higher velocity towards the edge of the showerhead, which is important to maintain proper purging.

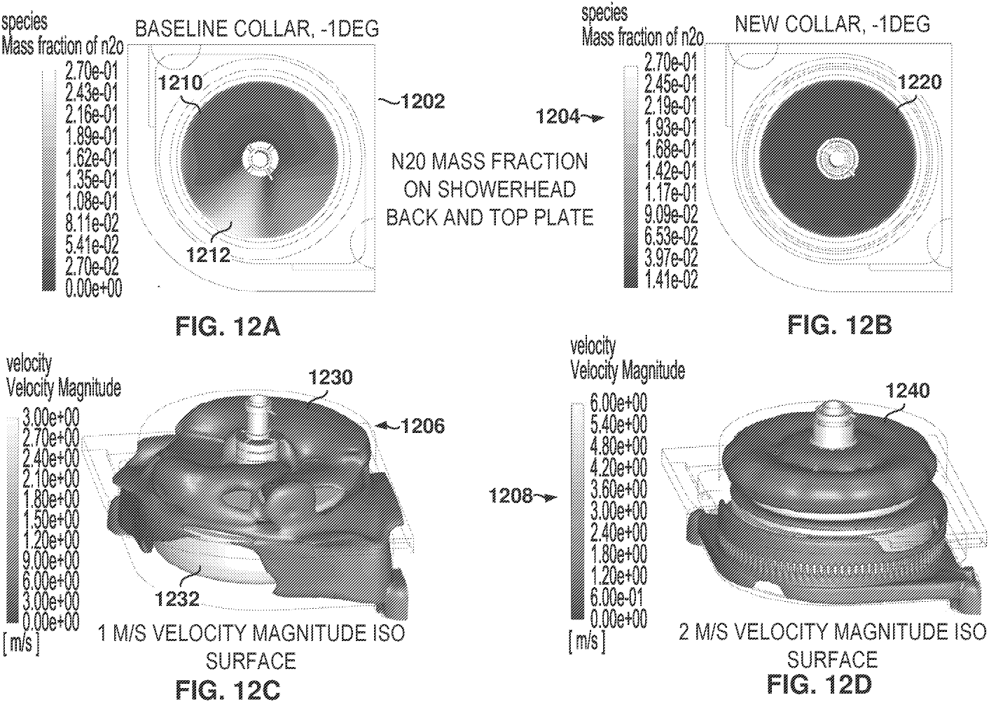

FIGS. 12A-12D show experiment results for the showerhead purge collar designs, according to some example embodiments. Chart 1202 shows a top view of N₂O mass fraction at the back of the showerhead for a 1° tilt of the showerhead using showerhead purge collar 206. The different colors correspond to different N₂O mass fraction in m/s.

The area 1210 shows low N₂O mass fraction, indicating good purging. The area 1212 shows high N₂O mass fraction, indicating poor purging.

FIG. 12C also corresponds to the first showerhead purge collar 206 and the area 1230 illustrates where the purge gas has a velocity of at least 1 m/s. It can be observed that area 1232 does not have a purge-gas flow of at least 1 m/s.

FIGS. 12B and 12D correspond to the showerhead purge collar 602 with the improved design using angled holes instead of horizontal slots. Chart 1204 shows low N₂O mass fraction, which means that the purge gas is doing a good job of preventing N₂O from coming into this area, even in the presence of the 1° tilt. Similarly, chart 1208 shows area 1240 where the purge gas flows at 2 m/s or more, which covers the hole circumference above the showerhead.

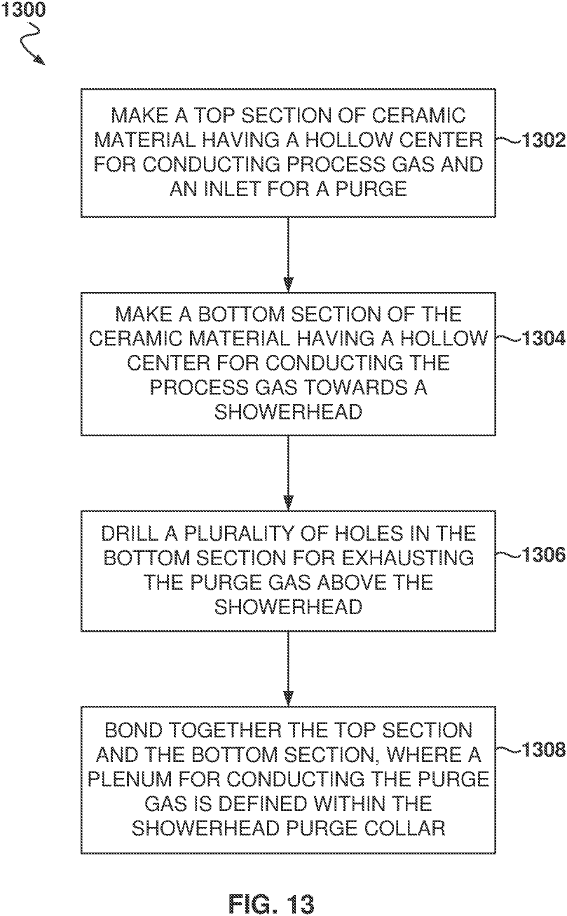

FIG. 13 is a flowchart of a method for manufacturing the showerhead purge collar, according to some example embodiments. While the various operations in this flowchart are presented and described sequentially, one of ordinary skill will appreciate that some or all of the operations may be executed in a different order, be combined or omitted, or be executed in parallel.

Operation 1302 is for making a top section of ceramic material. The top section has a hollow center for conducting process gas and an inlet for a purge gas on a side of the top section.

From operation 1302, the method flows to operation 1304 for making a bottom section of the ceramic material. The bottom section has a hollow center for conducting the process gas towards a showerhead.

At operation 1306, a plurality of holes is drilled in the bottom section for exhausting the purge gas above the showerhead. Other methods of hole formation are also possible.

From operation 1306, the method flows to operation 1308 where the top section and the bottom section are bonded together. The bottom section is concentric with the top section, and a plenum for conducting the purge gas is defined within the showerhead purge collar.

In one example, the plurality of holes in the bottom section extend in a line from the hollow center of the bottom section to an outside surface of the bottom section, the plurality of holes being oriented downwards at an angle from a horizontal plane.

In one example, the holes have a diameter in a range from 2 mm to 3 mm. In another example, the holes have a diameter in a range from 1 mm to 5 mm.

In one example, the plurality of holes is disposed in a plurality of rows around the bottom section.

In one example, the holes in one row are equally-spaced vertically between holes of a row above or a row below.

In one example, each row includes a number of holes in a range from 6 to 24.

In one example, the plurality of rows includes four rows and each row include 12 holes.

In one example, the plurality of rows includes a number of rows in a range from range from 2 to 6.

In one example, the plurality of rows includes four rows of holes.

In one example, the top section and the bottom section are ceramics.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. A showerhead purge collar, comprising:
a top section having a hollow center to conduct a process gas and an inlet to purge a gas on a side of the top section: and
a bottom section coupled to the top section and concentric with the top section, the bottom section having a hollow center to conduct the process gas towards a showerhead, wherein a plenum to conduct the purge gas is defined within the showerhead purge collar, the bottom section including a plurality of holes to exhaust the purge gas above the showerhead.

2. The showerhead purge collar as recited in claim 1, wherein the plurality of holes in the bottom section extend in a line from the hollow center of the bottom section to an outside surface of the bottom section, the line of the plurality of holes being oriented and extending downwards at an angle from a horizontal plane defined by a surface of the showerhead where the process gas enters a chamber.

3. The showerhead purge collar as recited in claim 2, wherein the holes have a diameter in a range from 2 mm to 3 mm.

4. The showerhead purge collar as recited in claim 2, wherein the holes have a diameter in a range from 1 mm to 5 mm.

5. The showerhead purge collar as recited in claim 1, wherein the plurality of holes is disposed in a plurality of rows around the bottom section.

6. The showerhead purge collar as recited in claim 5, wherein the holes in one row are equally-spaced vertically between holes of a row above or a row below.

7. The showerhead purge collar as recited in claim 5, wherein each row in the plurality of rows includes a number of holes in a range from 6 to 24.

8. The showerhead purge collar as recited in claim 5, wherein the plurality of rows includes four rows and each row include 12 holes.

9. The showerhead purge collar as recited in claim 5, wherein the plurality of rows includes a number of rows in a range from range from 2 to 6.

10. The showerhead purge collar as recited in claim 5, wherein the plurality of rows includes four rows of holes.

11. The showerhead purge collar as recited in claim 1, wherein the top section and the bottom section include ceramic materials.

12. A method for manufacturing a showerhead purge collar, the method comprising:
making a top section of ceramic material, the top section having a hollow center for conducting process gas and an inlet for a purge gas on a side of the top section;
making a bottom section of the ceramic material, the bottom section having a hollow center for conducting the process gas towards a showerhead:
drilling a plurality of holes in the bottom section for exhausting the purge gas above the showerhead; and
bonding together the top section and the bottom section, the bottom section being concentric with the top section, wherein a plenum for conducting the purge gas is defined within the showerhead purge collar.

13. The method as recited in claim 12, wherein the plurality of holes in the bottom section extend in a line from the hollow center of the bottom section to an outside surface of the bottom section, the plurality of holes being oriented downwards at an angle from a horizontal plane.

14. The method as recited in claim 12, wherein the holes have a diameter in a range from 2 mm to 3 mm.

15. The method as recited in claim 12, wherein the plurality of holes are disposed in a plurality of rows around the bottom section.

16. The method as recited in claim 15, wherein the holes in one row are equally-spaced vertically between holes of a row above or a row below.

17. The method as recited in claim 15, wherein each row includes a number of holes in a range from 6 to 24.

18. The method as recited in claim 15, wherein the plurality of rows includes four rows and each row includes 12 holes.

19. The method as recited in claim 15, wherein the plurality of rows includes a number of rows in a range from range from 2 to 6.

20. The method as recited in claim 15, wherein the plurality of rows includes four rows of holes.
